(19) United States
(12) Patent Application Publication
(10) Pub. No.: US 2025/0046520 A1
(43) Pub. Date: Feb. 6, 2025

(54) DOUBLE-SIDED COPPER CLAD LAMINATE, CAPACITOR ELEMENT AND PRINTED WIRING BOARD WITH BUILT-IN CAPACITOR, AND METHOD FOR MANUFACTURING DOUBLE-SIDED COPPER CLAD LAMINATE

(71) Applicant: MITSUI MINING & SMELTING CO., LTD., Tokyo (JP)

(72) Inventors: Ryuji ISHIZUKA, Ageo-shi (JP); Yoshihiro YONEDA, Ageo-shi (JP); Toshihiro HOSOI, Ageo-shi (JP); Yuji KAGEYAMA, Ageo-shi (JP)

(73) Assignee: MITSUI MINING & SMELTING CO., LTD., Tokyo (JP)

(21) Appl. No.: 18/704,680

(22) PCT Filed: Oct. 12, 2022
(86) PCT No.: PCT/JP2022/037980

§ 371 Date: Apr. 25, 2024

(30) Foreign Application Priority Data
Oct. 28, 2021 (JP) 2021-176712

(51) Int. Cl. H01G 4/14; H01G 4/008; H01G 4/35; H05K 1/16

(52) U.S. Cl. CPC H01G 4/14; H01G 4/35; H05K 1/162; H01G 4/008

(57) ABSTRACT

Provided is a double-sided copper clad laminate that can realize not only good capacitor characteristics but also excellent handleability. This double-sided copper clad laminate is a double-sided copper clad laminate having copper foil adhered onto both surfaces of a dielectric layer, wherein the dielectric layer has a thickness of 0.1 μm or more and 2.0 μm or less, and the double-sided copper clad laminate further includes a pair of resin layers arranged in contact with the copper foil between the dielectric layer and the copper foil.

### TECHNICAL FIELD

The present invention relates to a double-sided copper clad laminate, a capacitor element and a printed wiring board with built-in capacitor, and a method for manufacturing the double-sided copper clad laminate.

### BACKGROUND ART

Printed wiring boards are widely used in electronic communication devices such as portable electronic devices. In particular, as portable electronic communication devices and other devices have become lighter, thinner, shorter, smaller, and more highly functional in recent years, reducing noise in printed wiring boards has become an issue, for example. Capacitors are important for noise reduction, but in order to realize high functionality, it is desirable for capacitors to be small enough and thin enough to be incorporated into the inner layers of printed wiring boards. In order to form such capacitors, double-sided copper clad laminates are used. Double-sided copper clad laminates generally have a configuration in which a dielectric layer is sandwiched between copper foils on both sides, and dielectric layers are being made thinner in order to increase the capacitance of capacitors.

For example, Patent Literature 1 (JP2004-249480A) discloses a double-sided copper clad laminate having electrodeposited copper foil adhered onto both surfaces of a thin dielectric layer with a thickness of 3 μm or more and 10 μm or less, and describes that short circuits caused by proximity of the copper foil treated surfaces due to the thinning of the dielectric layer are prevented.

### CITATION LIST

### Patent Literature

Patent Literature 1: JP2004-249480A
Patent Literature 2: WO2015/033917A1
Patent Literature 3: WO2003/096776A1

### SUMMARY OF INVENTION

Patent Literature 1 discloses a double-sided copper clad laminate having, as a dielectric layer, a configuration in which a commercially available reinforcing material (heat resistant film) is provided between a pair of thermosetting resins (that is, a three-layer configuration of resin layer/heat resistant film layer/resin layer). However, since films available in the market, even thin ones, have a thickness of about 4 μm, it is difficult to realize further thinning of the dielectric layer with the technology disclosed in Patent Literature 1. In addition, even if further thinning of the dielectric layer could be achieved, there is concern that this would result in a decrease in the handleability of the double-sided copper clad laminate.

The inventors have recently found that, in a double-sided copper clad laminate, by making the thickness of the dielectric layer extremely thin, 0.1 μm or more and 2.0 μm or less, and by further providing resin layers between the dielectric layer and the copper foil, not only good capacitor characteristics but also excellent handleability can be realized.

Accordingly, an object of the present invention is to provide a double-sided copper clad laminate that can realize not only good capacitor characteristics but also excellent handleability.

The present invention provides the following aspects.

### [Aspect 1]

A double-sided copper clad laminate having copper foil adhered onto both surfaces of a dielectric layer,
wherein the dielectric layer has a thickness of 0.1 μm or more and 2.0 μm or less, and
wherein the double-sided copper clad laminate further comprises a pair of resin layers arranged in contact with the copper foil between the dielectric layer and the copper foil.

### [Aspect 2]

The double-sided copper clad laminate according to aspect 1, wherein a tensile strength of the resin layers is larger than a tensile strength of the dielectric layer.

### [Aspect 3]

The double-sided copper clad laminate according to aspect 1 or 2, wherein an overall tensile strength of the dielectric layer and the resin layers is 50 MPa or more and 200 MPa or less.

### [Aspect 4]

The double-sided copper clad laminate according to any one of aspects 1 to 3, wherein an overall puncture strength of the dielectric layer and the resin layers is 0.6 N or more.

### [Aspect 5]

The double-sided copper clad laminate according to any one of aspects 1 to 4, wherein at least one of the resin layers and the dielectric layer comprises a dielectric filler.

### [Aspect 6]

The double-sided copper clad laminate according to aspect 5, wherein when the dielectric layer comprises the dielectric filler, a content of the dielectric filler in the dielectric layer is 10 parts by weight or more and 90 parts by weight or less relative to 100 parts by weight of the dielectric layer.

### [Aspect 7]

The double-sided copper clad laminate according to aspect 5, wherein when the resin layers comprise the dielectric filler, a content of the dielectric filler in the resin layers is 10 parts by weight or more and 80 parts by weight or less relative to 100 parts by weight of the resin layers.

### [Aspect 8]

The double-sided copper clad laminate according to any one of aspects 5 to 7, wherein a content of the dielectric filler in the resin layers relative to 100 parts by weight of the resin layers is smaller than a content of the dielectric filler in the dielectric layer relative to 100 parts by weight of the dielectric layer.

### [Aspect 9]

The double-sided copper clad laminate according to any one of aspects 5, 6 and 8, wherein the resin layers are free from the dielectric filler and the dielectric layer comprises the dielectric filler.

### [Aspect 10]

The double-sided copper clad laminate according to aspect 9, wherein a content of the dielectric filler in the dielectric layer is 10 parts by weight or more and 90 parts by weight or less relative to 100 parts by weight of the dielectric layer.

### [Aspect 11]

The double-sided copper clad laminate according to any one of aspects 1 to 10, wherein a glass transition temperature Tg of resin contained in the resin layers is 180° C. or higher.

### [Aspect 12]

The double-sided copper clad laminate according to any one of aspects 1 to 11, wherein a glass transition temperature Tg of resin contained in the resin layers is higher than a glass transition temperature Tg of resin contained in the dielectric layer.

### [Aspect 13]

A capacitor element comprising the double-sided copper clad laminate according to any one of aspects 1 to 12.

### [Aspect 14]

A printed wiring board with built-in capacitor, comprising the double-sided copper clad laminate according to any one of aspects 1 to 12.

### [Aspect 15]

A method for manufacturing the double-sided copper clad laminate according to any one of aspects 1 to 12, comprising the steps of:
(i) applying a resin layer precursor to a copper foil;
(ii) curing the precursor to obtain a copper foil with resin layer;
(iii) arranging a dielectric layer on a surface of the resin layer; and
(iv) pressing the copper foil with resin layer on which the dielectric layer has been arranged and another copper foil with resin layer produced through the above steps (i) and (ii), so that the dielectric layer is sandwiched by the resin layers from both sides.

### BRIEF DESCRIPTION OF DRAWING

FIG. 1 is a schematic cross-sectional view of a double-sided copper clad laminate according to the present invention.

### DESCRIPTION OF EMBODIMENTS

### Double-Sided Copper Clad Laminate

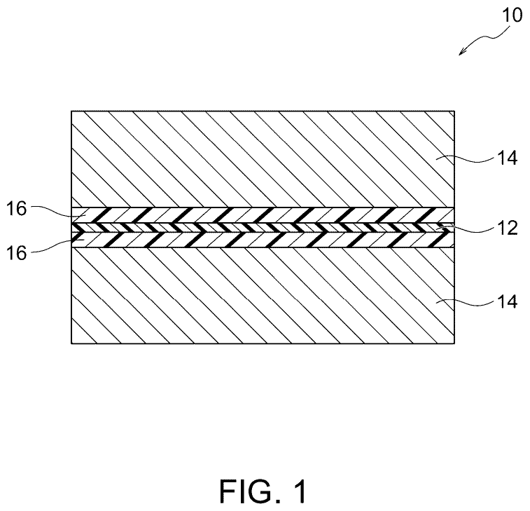

FIG. 1 is a schematic cross-sectional view of a double-sided copper clad laminate 10 according to the present invention. As shown in FIG. 1, the double-sided copper clad laminate 10 has copper foil 14 adhered onto both surfaces of a dielectric layer 12. The dielectric layer 12 has a thickness of 0.1 μm or more and 2.0 μm or less. The double-sided copper clad laminate 10 further includes a pair of resin layers 16 arranged in contact with the copper foil 14 between the dielectric layer 12 and the copper foil 14. In this manner, in the double-sided copper clad laminate 10, by making the thickness of the dielectric layer 12 extremely thin, 0.1 μm or more and 2.0 μm or less, and by further providing the resin layers 16 between the dielectric layer 12 and the copper foil 14, not only good capacitor characteristics but also excellent handleability can be realized.

As described above, Patent Literature 1 discloses a double-sided copper clad laminate having, as a dielectric layer, a configuration in which a commercially available reinforcing material (heat resistant film) is provided between a pair of thermosetting resins (that is, a three-layer configuration of resin layer/heat resistant film layer/resin layer). However, since films available in the market, even thin ones, have a thickness of about 4 μm, it is difficult to realize further thinning of the dielectric layer with the technology disclosed in Patent Literature 1. In addition, even if further thinning of the dielectric layer could be achieved, there is concern that this would result in a decrease in the handleability of the double-sided copper clad laminate. For example, in the case where such a double-sided copper clad laminate is subjected to double-sided etching to etch away the copper foil and expose the resin layers, the strength of the dielectric layer may decline along with the thinning, causing it to be cracked. In this respect, the double-sided copper clad laminate of the present invention conveniently solves such problems.

The dielectric layer 12 has a thickness of 0.1 μm or more and 2.0 μm or less, more preferably 0.3 μm or more and 1.8 μm or less, and still more preferably 0.5 μm or more and 1.5 μm or less. By making the dielectric layer 12 extremely thin in this manner, even higher capacitance of the capacitor can be realized.

The dielectric layer 12 is preferably composed of a resin composition containing a resin component and, optionally, a dielectric filler. This resin component is composed of a thermoplastic component and/or a thermosetting component. Specifically, it preferably contains at least one selected from the group consisting of epoxy resins, polyethylene terephthalate resins, polyethylene naphthalate resins, polyvinylcarbazole resins, polyphenylene sulfide resins, polyamide resins, aromatic polyamide resins, polyamideimide resins, polyimide resins, polyethersulfone resins, polyethernitrile resins, polyether ether ketone resins, polytetrafluoroethylene resins, urethane resins, isocyanate resins, active ester resins, phenolic resins, and diamine compounds, and more preferably contains at least one selected from the group consisting of epoxy resins, active ester resins, phenolic resins, and diamine compounds.

The dielectric layer 12 preferably contains a dielectric filler that is a composite metal oxide containing at least two selected from the group consisting of Ba, Ti, Sr, Pb, Zr, La, Ta, Ca, and Bi. This composite metal oxide more preferably contains at least two selected from the group consisting of Ba, Ti, and Sr. By doing so, a double-sided copper clad laminate that provides good capacitor characteristics even when thinning is performed can be obtained more effectively. The composite metal oxide preferably contains at least one selected from the group consisting of BaTiO₃, BaTi₄O₉, SrTiO₃, Pb(Zr,Ti)O₃, PbLaTiO₃, PbLaZrO, and SrBi₂Ta₂O₉, and more preferably contains at least one selected from the group consisting of BaTiO₃ and SrTiO₃. Note that Pb(Zr,Ti)O₃ means Pb(ZrₓTi₁₋ₓ)O₃, wherein 0≤x≤1, typically 0<x<1. By doing so, a double-sided copper clad laminate that provides good capacitor characteristics even when thinning is performed can be obtained more effectively.

In the case where the dielectric layer 12 contains a dielectric filler, the content of the dielectric filler in the dielectric layer 12 is preferably 10 parts by weight or more and 90 parts by weight or less, more preferably 15 parts by weight or more and 85 parts by weight or less, and still more preferably 25 parts by weight or more and 80 parts by weight or less, relative to 100 parts by weight of the dielectric layer 12 (100 parts by weight of solid content of the resin composition contained in the dielectric layer, including the weight of not only the resin component but also the dielectric filler).

Although the particle size of the dielectric filler that is a composite metal oxide is not particularly limited, from the viewpoint of uniform dispersion of the filler in the resin component, the average particle size D₅₀ as measured by laser diffraction scattering particle size distribution measurement is preferably 0.001 μm or more and 2.0 μm or less, more preferably 0.01 μm or more and 1.8 μm or less, and still more preferably 0.03 μm or more and 1.6 μm or less.

The dielectric layer 12 may further contain a filler dispersant. By further containing a filler dispersant, the dispersibility of the dielectric filler can be improved when the resin varnish and the dielectric filler are mixed together. As the filler dispersant, any usable known filler dispersants can be used as appropriate, and there is no particular limitation on it. Preferred examples of the filler dispersant include ionic dispersants such as phosphonic acid, cationic, carboxylic acid, and anionic dispersants, as well as nonionic dispersants such as ether, ester, sorbitan ester, diester, monoglyceride, ethylene oxide adduct, ethylene diamine-based, and phenolic dispersants. In addition, examples thereof include coupling agents such as silane coupling agents, titanate coupling agents, and aluminate coupling agents.

A curing accelerator may be added to the resin composition used for the dielectric layer 12 in order to accelerate the curing of the resin component. Preferred examples of the curing accelerator include imidazole-based curing accelerators and amine-based curing accelerators. From the viewpoint of storage stability of the resin component contained in the resin composition and efficiency of curing, the content of the curing accelerator is preferably 0.01 parts by weight or more and 3.0 parts by weight or less, more preferably 0.1 parts by weight or more and 2.0 parts by weight or less, relative to 100 parts by weight of the non-volatile component in the resin composition.

The pair of resin layers 16 are arranged in contact with the copper foil 14 between the dielectric layer 12 and the copper foil 14, which contributes to improving the handleability of the double-sided copper clad laminate 10. Accordingly, even if the double-sided copper clad laminate 10 is subjected to double-sided etching to etch away the copper foil and expose the three-layer configuration of resin layer 16/dielectric layer 12/resin layer 16, it will still exhibit excellent strength and be less likely to be cracked. From such a viewpoint, the thickness of each of the resin layers 16 is preferably 0.1 μm or more and 4.0 μm or less, more preferably 0.5 μm or more and 3.5 μm or less, and still more preferably 1.5 μm or more and 2.5 μm or less. Accordingly, the overall thickness of the dielectric layer 12 and the resin layers 16 (that is, the three-layer configuration of resin layer 16/dielectric layer 12/resin layer 16) is preferably 0.3 μm or more and 10 μm or less, more preferably 1.3 μm or more and 8.8 μm or less, and still more preferably 3.5 μm or more and 6.5 μm or less.

The resin layers 16 are preferably composed of a resin composition containing a resin component and, optionally, a dielectric filler. This resin component preferably contains at least one selected from the group consisting of epoxy resins, polyethylene terephthalate, polyethylene naphthalate, polyvinylcarbazole, polyphenylene sulfide, polyimide, polyamide, aromatic polyamide (for example, fully aromatic polyamide), polyamideimide, polyethersulfone, polyethernitrile, polyether ether ketone, and polytetrafluoroethylene, more preferably contains at least one selected from the group consisting of polyphenylene sulfide, polyimide, polyamide, polyamideimide, and fully aromatic polyamide (aramid), and still more preferably contains at least one selected from the group consisting of polyimide, polyamide, and fully aromatic polyamide (aramid). By using the above resin components, the resin layers become tough, and even if the resin layers are made thinner or a dielectric filler is introduced, the handleability can be effectively guaranteed. Also, while the resin layers constituting the double-sided copper clad laminate are a pair of resin layers that are in contact with the copper foil, one resin layer and the other resin layer may be composed of different components.

The resin layers 16 may contain a dielectric filler. As this dielectric filler, those of the same type and particle size as the dielectric filler contained in the dielectric layer 12 described above can be used. By doing so, a double-sided copper clad laminate 10 that provides good capacitor characteristics even when thinning is performed can be obtained more effectively. In the case where the resin layers 16 contain a dielectric filler, the content of the dielectric filler in the resin layers 16 is preferably 10 parts by weight or more and 80 parts by weight or less, more preferably 15 parts by weight or more and 70 parts by weight or less, and still more preferably 20 parts by weight or more and 65 parts by weight or less, relative to 100 parts by weight of the resin layers 16 (100 parts by weight of solid content of the resin composition contained in the resin layers, including the weight of not only the resin component but also the dielectric filler). The resin layers 16 may further contain a filler dispersant. As this filler dispersant, those of the same type as the filler dispersant contained in the dielectric layer described above can be used. On the other hand, in the case where it is desired to specialize in ensuring higher handleability, it is preferable for the resin layers 16 to be free from the dielectric filler. That is, it is preferable that the resin layers 16 are free from the dielectric filler and the dielectric layer 12 contains the dielectric filler. At this time, the content of the dielectric filler in the dielectric layer 12 is preferably 10 parts by weight or more and 90 parts by weight or less relative to 100 parts by weight of the dielectric layer 12.

As described above, the dielectric layer 12 and the resin layers 16 may contain a dielectric filler. That is, the double-sided copper clad laminate 10 preferably contains a dielectric filler in at least one or both of the resin layers 16 and the dielectric layer 12. It is also preferable that the content of the dielectric filler in the resin layers relative to 100 parts by weight of the resin layers is smaller than the content of the dielectric filler in the dielectric layer relative to 100 parts by weight of the dielectric layer. By doing so, while maintaining good capacitor characteristics, both insulating properties and handleability can be achieved.

The glass transition temperature Tg of resin contained in the resin layers 16 is preferably 180° C. or higher, more preferably 200° C. or higher and 350° C. or lower, and still more preferably 220° C. or higher and 330° C. or lower. It is also preferable that the glass transition temperature Tg of resin contained in the resin layers 16 is higher than the glass transition temperature Tg of resin contained in the dielectric layer 12. By controlling Tg in such a range, handleability can be ensured even at high temperatures, which can further improve the yield in the manufacturing process.

The tensile strength of the resin layers 16 is preferably larger than the tensile strength of the dielectric layer 12. This tensile strength is preferably measured in accordance with JIS K7161 at 25° C., providing samples of the same thickness for the resin layers 16 and the dielectric layer 12. By making the tensile strength of the resin layers 16 larger than the tensile strength of the dielectric layer 12, good handleability can be effectively realized. In addition, the overall tensile strength of the dielectric layer 12 and the resin layers 16 is preferably 50 MPa or more and 200 MPa or less, more preferably 80 MPa or more and 150 MPa or less. The tensile strength of the dielectric layer 12 alone is preferably 20 MPa or more and 80 MPa or less, more preferably 40 MPa or more and 80 MPa or less. The tensile strength of the resin layers 16 alone is preferably 80 MPa or more and 250 MPa or less, more preferably 100 MPa or more and 250 MPa or less. Note that, from the viewpoint of carrying out more accurate measurement, it is preferable to produce samples of the same thickness for the resin layers 16 and the dielectric layer 12 to evaluate the tensile strength thereof.

The puncture strength of the resin film (the dielectric layer 12 and the resin layers 16 as a whole) in the double-sided copper clad laminate 10 is preferably 0.6 N or more, more preferably 1.2 N or more, still more preferably 1.5 N or more, and particularly preferably 2.4 N or more. By making the puncture strength in the above range, even if the resin in the area where no circuit exists is exposed when forming a capacitor circuit by etching in the manufacturing process for a printed wiring board with built-in capacitor, it can withstand the etching solution and the water pressure when carrying out a rinsing shower with water, etc. Therefore, good handleability for practical use can be ensured. Although the upper limit of the puncture strength is not particularly restricted, it is typically 5.0 N or less from the viewpoint of resin material design. Evaluation of puncture strength can be carried out in accordance with JIS Z1707:2019 “General rules of plastic films for food packaging”.

The maximum peak height Sp on a surface of the copper foil 14, as measured in accordance with ISO 25178, on the side in contact with the resin layers 16 is preferably 0.05 μm or more and 3.3 μm or less, more preferably 0.06 μm or more and 3.1 μm or less, still more preferably 0.06 μm or more and 3.0 μm or less, and particularly preferably 0.07 μm or more and 2.9 μm or less. From the viewpoint of attempting to obtain a particularly thin double-sided copper clad laminate, the maximum peak height Sp is even more preferably 2.5 μm or less, even further preferably 1.7 μm or less, and most preferably 1.1 μm or less. By controlling the surface properties of the copper foil in this manner, it is possible to more effectively obtain a double-sided copper clad laminate that can demonstrate excellent handleability while ensuring high capacitor capacitance when used as a capacitor. Note that the “maximum peak height Sp” is a three-dimensional parameter that represents the maximum value of the height from the average surface of the surface, as measured in accordance with ISO 25178.

The root mean square gradient Sdq on a surface of the copper foil 14, as measured in accordance with ISO 25178, on the side in contact with the resin layers 16 is preferably 0.01 or more and 2.3 or less, more preferably 0.02 or more and 2.2 or less, still more preferably 0.03 or more and 2.0 or less, and particularly preferably 0.04 or more and 1.8 or less. From the viewpoint of attempting to obtain a particularly thin double-sided copper clad laminate, the root mean square gradient Sdq is even more preferably 1.6 or less, even further preferably 1.3 or less, and most preferably 0.4 or less. By controlling the surface properties of the copper foil in this manner, it is possible to more effectively obtain a double-sided copper clad laminate that can demonstrate excellent handleability while ensuring high capacitor capacitance when used as a capacitor. Note that the “root mean square gradient Sdq” is a parameter calculated from the root mean square of the gradient at all points in the defined region, as measured in accordance with ISO 25178. That is, it is a three-dimensional parameter that evaluates the magnitude of the local slope angle, and thus can numericize the steepness of the surface irregularities. For example, the Sdq on a perfectly flat surface is 0, and if the surface is sloped, the Sdq becomes larger. The Sdq of a plane composed of a 45 degree sloped component is 1.

The kurtosis Sku on a surface of all of the copper foil 14, as measured in accordance with ISO 25178, on the side in contact with the resin layers is preferably 2.6 or more and 4.0 or less, more preferably 2.7 or more and 3.8 or less, and still more preferably 2.7 or more and 3.7 or less. In this manner, by controlling the kurtosis Sku in addition to controlling the maximum peak height Sp and the root mean square gradient Sdq as surface properties of the copper foil, the desired double-sided copper clad laminate can be obtained more effectively. Note that the “kurtosis Sku” is a parameter that represents the sharpness of the height distribution, as measured in accordance with ISO 25178, and is also referred to as the degree of peakedness. Sku=3 means that the height distribution is a normal distribution, Sku>3 means that the surface has many sharp peaks and valleys, and Sku<3 means that the surface is flat.

Although the thickness of the copper foil 14 is not particularly limited, it is preferably 0.1 μm or more and 200 μm or less, more preferably 0.5 μm or more and 105 μm or less, and still more preferably 1.0 μm or more and 70 μm or less. By doing so, it is possible to employ methods such as the subtractive process, semi-additive process (SAP), and modified semi-additive process (MSAP), which are common methods for forming wiring patterns on printed wiring boards.

As described above, the double-sided copper clad laminate 10 shown in FIG. 1 has a five-layer configuration of copper foil 14/resin layer 16/dielectric layer 12/resin layer 16/copper foil 14, but the present invention is not limited to this five-layer configuration. That is, the double-sided copper clad laminate of the present invention may include other layers (for example, between the dielectric layer 12 and the resin layers 16).

Capacitor Element and Printed Wiring Board with Built-In Capacitor

The double-sided copper clad laminate of the present invention is preferably incorporated into a capacitor element. That is, according to a preferred aspect of the present invention, there is provided a capacitor element including the double-sided copper clad laminate described above. The configuration of the capacitor element is not particularly limited, and any known configuration can be employed. A particularly preferred form is a printed wiring board with built-in capacitor, in which a capacitor is incorporated as an inner layer portion of the printed wiring board. That is, according to a particularly preferred aspect of the present invention, there is provided a printed wiring board with built-in capacitor including the double-sided copper clad laminate described above. The capacitor element and the printed wiring board with built-in capacitor can be manufactured based on known methods.

### Method for Manufacturing Double-Sided Copper Clad Laminate

A preferred method for manufacturing the double-sided copper clad laminate of the present invention includes the steps of: (i) applying a resin layer precursor to a copper foil; (ii) curing the precursor to obtain a copper foil with resin layer; (iii) arranging a dielectric layer on a surface of the resin layer; and (iv) pressing the copper foil with resin layer on which the dielectric layer has been arranged and another copper foil with resin layer produced through the above steps (i) and (ii), so that the dielectric layer is sandwiched by the resin layers from both sides.

### (i) Step of Applying Resin Layer Precursor to Copper Foil

At first, a resin layer precursor is provided. This precursor becomes a resin layer after curing. As described above, there is a limit on the thinness of commercially available products used for the layer corresponding to the resin layer, and it is desired to make the resin layer further thinner. In this respect, by using the precursor described above, the resin layer after curing can be effectively made thinner. For the raw material component for resin varnish as the precursor, polyamide acid, polyamideimide, or precursors thereof can be used, for example. This raw material component for resin varnish and, optionally, a slurry containing a dielectric filler or the like are mixed to obtain a coating solution. This coating solution is applied to the copper foil so that the thickness of the resin layer after drying becomes a predetermined value. The method of application is arbitrary, but in addition to the gravure coating method, the die coating method, knife coating method, etc. can be employed. Besides, it is also possible to perform application using a doctor blade, bar coater, etc.

(ii) Step of Curing Precursor to Obtain Copper Foil with Resin Layer

The copper foil to which the precursor has been applied is cured. Although the method of curing is not particularly limited, for example, the precursor can be dried in a heated oven to a semi-cured state, and then heated at a higher temperature in a conveyor furnace or an oven. Thus, a copper foil with resin layer can be obtained. Instead of using a commercially available product for the resin layer, by applying and thermally curing the precursor through the above step (i) and this step, it is possible to effectively realize thinning of the resin layer and higher dielectricity of the resin layer through the introduction of a dielectric filler. Furthermore, such a resin layer is tough and can effectively guarantee handleability even when it is thinned or a dielectric filler is introduced.

(iii) Step of Arranging Dielectric Layer on Surface of Resin Layer

At first, a raw material component for resin varnish used for the dielectric layer is provided. For this raw material component for resin varnish, the resin components used for the dielectric layer described above can be used. This raw material component for resin varnish and, optionally, a slurry containing a dielectric filler or the like are mixed to obtain a coating solution. This coating solution is applied to the resin layer of the copper foil with resin layer so that the thickness of the dielectric layer after drying becomes a predetermined value. The method of application is arbitrary, but in addition to the gravure coating method, the die coating method, knife coating method, etc. can be employed. Besides, it is also possible to perform application using a doctor blade, bar coater, etc. After application, it may be heated if necessary.

### (iv) Step of Pressing

The copper foil with resin layer on which the dielectric layer has been arranged and another copper foil with resin layer produced through the above steps (i) and (ii) or the above steps (i), (ii), and (iii) are pressed so that the dielectric layer is sandwiched by the resin layers from both sides. At this time, heating or vacuuming the atmosphere may be performed if necessary. Thus, a double-sided copper clad laminate can be preferably manufactured.

Between the above step (ii) and the above step (iii), it is preferable to conduct a step of subjecting the surface of the resin layer of the copper foil with resin layer to a roughening treatment. Examples of the method of surface roughening treatment include a plasma treatment, a corona discharge treatment, and a sandblasting treatment. By performing such a surface roughening treatment, the area of the contact interface between the resin layer and the dielectric layer can be increased to improve adhesion (peel strength) and delamination can be avoided. More preferred examples of the surface roughening treatment for the resin layer include a plasma treatment and a corona discharge treatment.

### EXAMPLES

The present invention will be described more specifically by the following examples.

### Examples 1 to 6

### (1) Provision of Coating Solution for Dielectric Layer

### (1a) Preparation of Resin Varnish for Dielectric Layer

At first, the resin components and imidazole-based curing accelerator shown below were provided as raw material components for resin varnish.
Biphenyl-aralkyl epoxy resin: NC-3000 manufactured by Nippon Kayaku Co., Ltd.
Polyfunctional phenolic resin (curing agent): MEH-7500 manufactured by Meiwa Plastic Industries, Ltd.
Phenolic hydroxyl group-containing polybutadiene-modified aromatic polyamide resin: BPAM-155 manufactured by Nippon Kayaku Co., Ltd.
Imidazole-based epoxy resin curing accelerator: 2P4MHZ manufactured by Shikoku Chemicals Corporation

The above raw material components for resin varnish were weighed in the formulation ratios (weight ratios) shown in Tables 1A and 1B. Thereafter, a cyclopentanone solvent was weighed, and the raw material components for resin varnish and the cyclopentanone solvent were put into a flask and stirred at 60° C. After confirming that there was no undissolved residue of raw materials in the resin varnish and that the resin varnish was clear, the resin varnish was collected.

(1b) Mixing with Filler

Subsequently, the dielectric filler and dispersant shown below were provided.
Barium titanate: manufactured by Nippon Chemical Industrial Co., Ltd.
Titanate coupling agent: KR-44 manufactured by Ajinomoto Fine-Techno Co., Inc. (amount added: 1.5 parts by weight relative to 100 parts by weight of dielectric filler)

A cyclopentanone solvent, the dielectric filler, and the dispersant were each weighed. The weighed solvent, dielectric filler, and dispersant were made into a slurry using a dispersing machine. After this slurrification was confirmed, the resin varnish was weighed so that the final dielectric filler was at the formulation ratios (weight ratios) shown in Tables 1A and 1B, and mixed together with the dielectric filler-containing slurry in the dispersing machine. After mixing, the dielectric filler was confirmed not to be agglomerated. Thus, a coating solution for dielectric layer was obtained.

### (2) Provision of Coating Solution for Resin Layer

### (2a) Preparation of Resin Varnish for Resin Layer

The resin component shown below was provided as a raw material component for resin varnish used for the resin layer.
Polyamide acid varnish: manufactured by Ube Industries, Ltd.
   (2b) Mixing with Filler

Subsequently, the dielectric filler and dispersant shown below were provided.
Barium titanate: manufactured by Nippon Chemical Industrial Co., Ltd.
Titanate coupling agent: KR-44 manufactured by Ajinomoto Fine-Techno Co., Inc. (amount added: 1.5 parts by weight relative to 100 parts by weight of dielectric filler)

A NMP (N-methyl-2-pyrrolidone) solvent, the dielectric filler, and the dispersant were each weighed. The weighed solvent, dielectric filler, and dispersant were made into a slurry with a dispersing machine. After this slurrification was confirmed, the resin varnish was weighed so that the final dielectric filler was at the formulation ratios (weight ratios) shown in Tables 1A and 1B, and mixed together with the dielectric filler-containing slurry in the dispersing machine. After mixing, the dielectric filler was confirmed not to be agglomerated. Thus, a coating solution for resin layer was obtained.

### (3) Provision of Copper Foil

As copper foil to which the above coating solution was to be applied, a roughened copper foil was provided. The manufacturing of this copper foil was carried out by known methods such as those disclosed in Patent Literature 2, Patent Literature 3, etc.

### (4) Application of Coating Solution

The coating solution for resin layer obtained in (2) above was applied to the copper foil provided in (3) above using a bar coater so that the thickness of the resin layer after drying would be the thicknesses shown in Tables 1A and 1B, and then dried in an oven heated to 150° C. for 3 minutes to make the resin in a semi-cured state. Thus, a copper foil with resin layer was obtained.

(5) Annealing Treatment for Copper Foil with Resin Layer

The copper foil with resin layer obtained in (4) above was subjected to an annealing treatment using a small conveyor furnace (810A-II manufactured by Koyo Thermo Systems Co., Ltd.) to obtain a copper foil with resin layer in which the resin layer was in a cured state. The highest set temperature in the small conveyor furnace was set at 360° C. and the conveyor speed was set at 40 mm/minute.

(6) Plasma Treatment for Copper Foil with Resin Layer (Roughening Treatment for Resin Layer Surface)

The copper foil with resin layer obtained in (5) above was subjected to a plasma treatment under the following conditions.
Apparatus used: Plasma Cleaner (PC-1100 manufactured by Samco Inc.)
Treatment gas type: Ar
Gas flow rate: 40 sccm
Output: 500 W
Treatment time: 30 seconds

### (7) Application of Coating Solution

On the resin layer side of the copper foil with resin layer obtained in (6) above, the coating solution for dielectric layer obtained in (1) above was applied using a bar coater so that the thickness of the dielectric layer after drying would be the thicknesses shown in Tables 1A and 1B, and then dried in an oven heated to 150° C. for 3 minutes to make the resin in a semi-cured state. Thus, a copper foil with resin layer including a dielectric layer was obtained.

### (8) Pressing Treatment

The copper foil with resin layer including a dielectric layer obtained in (7) above was placed with the dielectric layer side surface facing up, and on that dielectric layer side surface, another copper foil with resin layer obtained in (6) above was placed with the resin layer side surface facing down. At this time, vacuum pressing was carried out at 180° C. for 120 minutes to make the dielectric layer in a cured state. Thus, a double-sided copper clad laminate with a five-layer configuration of copper foil/resin layer/dielectric layer/resin layer/copper foil was obtained, with the resin layer and copper foil on both sides of the dielectric layer.

### (9) Cross-Sectioning and Observation of Double-Sided Copper Clad Laminate

Cross-sectioning of the double-sided copper clad laminate was carried out using a microtome, and cross-sectional observation (measurement of the thickness of the resin layer and the dielectric layer) was carried out by optical microscopy. Note that, although depending on the formulation of resin components and dielectric filler, when the resin layer and the dielectric layer have a thickness region of several micrometers or less, it may be difficult to see the boundary of each layer using an optical microscope. In that case, other known cross-sectioning and observation methods (for example, FIB processing and SIM observation) can be used for confirmation, if necessary.

### (10) Evaluations

The following various evaluations were carried out for the obtained double-sided copper clad laminates.

### <Evaluation 1: Tg (Glass Transition Temperature)>

The Tg of the resin layer and the dielectric layer was measured. Specifically, (i) after applying the coating solution for resin layer to copper foil, this coating solution was cured to obtain a copper foil with resin layer. All copper on this copper foil with resin layer was etched away to produce a resin film (resin layer only) with a thickness of 12 μm, and the Tg was measured. Also, (ii) after applying the coating solution for dielectric layer to copper foil, this coating solution was cured to obtain two copper foils with dielectric layer. The dielectric layers of these two copper foils with dielectric layer were faced to each other and adhered by pressing to obtain a double-sided copper clad laminate. All copper on both sides of this double-sided copper clad laminate was etched away to produce a resin film (dielectric layer only) with a thickness of 12 μm, and the Tg was measured.

At this time, about 5 mg of the resin film was weighed and measurement was performed from normal temperature (for example, 25° C.) to 350° C. at a temperature increase rate of 10° C./minute using a DSC (DSC7000X manufactured by Hitachi High-Tech Science Corporation). From the obtained chart, the temperature of the shifted portion of the baseline was read, and that temperature was used as the Tg (glass transition temperature) of the resin film. This measurement was carried out in accordance with IPC-TM-650 2.4.25. As a result, the Tg of the dielectric layer was 174° C. and the Tg of the resin layer was 252° C.

### <Evaluation 2: Capacitance (Cp) and Dielectric Tangent (Df)>

A circular circuit with a diameter of 0.5 inches (12.6 mm) was etched on one side of the double-sided copper clad laminate, and then the Cp (nF/in²) and the Df were measured at a frequency of 1 MHz using an LCR meter (LCR HiTESTER 3532-50 manufactured by Hioki E.E. Corporation). This measurement was carried out in accordance with IPC-TM-650 2.5.2. The results were as shown in Table 2.

### <Evaluation 3: Breakdown Voltage (BDV)>

A circular circuit with a diameter of 0.5 inches (12.6 mm) was etched on one side of the double-sided copper clad laminate, and then the breakdown voltage (kV) was measured under the conditions with a voltage boost rate of 167 V/sec using an insulation resistance measuring instrument (Super Megohm Meter SM7110 manufactured by Hioki E.E. Corporation). This measurement was carried out in accordance with IPC-TM-650 2.5.6.2a. The results were as shown in Table 2.

### <Evaluation 4: Peel Strength in Normal State (Circuit Adhesion)>

A straight-line circuit with a width of 3 mm was etched on one side of the double-sided copper clad laminate, and then the circuit was peeled off using Autograph at a peeling speed of 50 mm/minute and its peel strength (kgf/cm) was measured at normal temperature (for example, 25° C.). This measurement was carried out in accordance with IPC-TM-650 2.4.8. The results were as shown in Table 2.

<Evaluation 5: Peel Strength after Heating (Circuit Adhesion)>

A straight-line circuit with a width of 3 mm was etched on one side of the double-sided copper clad laminate, which was then subjected to a baking treatment in an oven set at 260° C. for 45 minutes. After the baking treatment, the circuit was peeled off from the sample using Autograph at a peeling speed of 50 mm/minute and its peel strength (kgf/cm) was measured at normal temperature (for example, 25° C.). This measurement was carried out in accordance with IPC-TM-650 2.4.8. The results were as shown in Table 2.

### <Evaluation 6: Tensile Strength and Elongation>

All copper on both sides of the double-sided copper clad laminate was etched away to obtain a resin film (resin layers and dielectric layer). This resin film was cut into strips with a width of 10 mm and a length of 100 mm, and pulled using Autograph at a tensile speed of 50 mm/minute, and its tensile strength (MPa) and elongation (%) were measured at normal temperature (for example, 25° C.). Also, the same measurements were performed using the resin film with a thickness of 12 μm (resin layer only) and the resin film with a thickness of 12 μm (dielectric layer only) produced in Evaluation 1 above, thereby measuring their respective tensile strengths. Thus, not only the overall tensile strength of the resin film (resin layers and dielectric layer), but also the tensile strength of the resin layer and the dielectric layer were measured. This measurement was carried out in accordance with JIS K7161. The results were as shown in Table 2.

### <Evaluation 7: Puncture Strength>

All copper on both sides of the double-sided copper clad laminate was etched away to obtain a resin film (resin layers and dielectric layer). This resin film was cut into pieces of 50 mm×50 mm, and set in a fixture. Puncture was made at a test speed of 50 mm/minute using Autograph in which a puncture needle with a tip radius of 0.5 mm was set, and the puncture strength (N) was measured at normal temperatures (for example, 25° C.). This measurement was carried out in accordance with JIS Z1707:2019 “General rules of plastic films for food packaging”. The results were as shown in Table 2.

### Example 7 (Comparative)

A double-sided copper clad laminate was produced in the same manner as in Examples 4 to 6, except that no resin layer was formed. That is, the coating solution for dielectric layer was applied to a copper foil, and another copper foil was adhered onto the obtained coated foil, resulting in a double-sided copper clad laminate. Thus, a double-sided copper clad laminate with a three-layer configuration of copper foil/dielectric layer/copper foil free from resin layer was obtained. The double-sided copper clad laminate obtained in this example had problems such as embrittlement of resin film (dielectric layer), and the various evaluations described above could not be carried out.

### Example 8 (Comparative)

An attempt was made to produce a double-sided copper clad laminate in the same manner as in Examples 3 and 6, except that no dielectric layer was formed. That is, an attempt was made to obtain a double-sided copper clad laminate with a three-layer configuration of copper foil/resin layer/copper foil free from dielectric layer. However, the copper foils with resin layer could not be adhered together, and a double-sided copper clad laminate could not be obtained. Therefore, the various evaluations described above could not be carried out.

TABLE 1A

| | | | | | | |
|---|---|---|---|---|---|---|
| Component | Formulation | Manufacturer and product No. | Ex. 1 | Ex. 2 | Ex. 3 | Ex. 4 |

| | | | | | |
|---|---|---|---|---|---|
| Dielectric | Biphenyl-aralkyl epoxy resin | Resin component formulation | Nippon Kayaku Co., Ltd. | NC-3000 | 51 |
| layer | Polyfunctional phenolic | ratio (parts by weight relative to | Meiwa Plastic | MEH-7500 | 18 |
| | resin (curing agent) | 100 parts by weight of total | Industries, Ltd. | | |
| | Phenolic hydroxyl group- | resin components) | Nippon Kayaku Co., Ltd. | BPAM-155 | 31 |
| | containing polybutadiene- | | | | |
| | modified aromatic | | | | |
| | polyamide resin | | | | |
| | Imidazole-based epoxy | | Shikoku Chemicals | 2P4MHZ | 0.4 |
| | resin curing agent | | Corporation | | |

| | Barium titanate | Dielectric filler content (parts | Nippon Chemical Industrial Co., Ltd. | 0 | 0 | 0 | 75 |
|---|---|---|---|---|---|---|---|
| | | by weight relative to 100 parts | | | | | |
| | | by weight of dielectric layer) | | | | | |
| | Thickness (μm) | | | 1.2 | 1.2 | 1.1 | 1.1 |
| Resin | Polyamide acid varnish | Resin component formulation | Ube Industries, Ltd. | 100 | | | |
| layers | | ratio (parts by weight relative to | | | | | |
| | | 100 parts by weight of total | | | | | |
| | | resin components) | | | | | |
| | Barium titanate | Dielectric filler content (parts | Nippon Chemical Industrial Co., Ltd. | 0 | 20 | 40 | 0 |
| | | by weight relative to 100 parts | | | | | |
| | | by weight of resin layers) | | | | | |

| | | | | |
|---|---|---|---|---|
| Thickness of each layer (μm) | 2.5 | 2.2 | 2.0 | 2.4 |

| | | | | |
|---|---|---|---|---|
| Overall thickness of dielectric and resin layers in double-sided copper clad laminate (μm) | 6.2 | 5.6 | 5.1 | 5.9 |

TABLE 1B

| | Component | Formulation | Manufacturer and product No. | | Ex. 5 | Ex. 6 | Ex. 7* | Ex. 8* |
|---|---|---|---|---|---|---|---|---|
| Dielectric | Biphenyl-aralkyl | Resin component | Nippon Kayaku Co., | NC- | 51 | | | — |
| layer | epoxy resin | formulation | Ltd. | 3000 | | | | |
| | Polyfunctional | ratio (parts | Meiwa Plastic | MEH- | 18 | | | — |
| | phenolic resin | by weight | Industries, Ltd. | 7500 | | | | |
| | (curing agent) | relative to | Nippon Kayaku Co., | BPAM- | 31 | | | — |
| | Phenolic hydroxyl | 100 parts by | Ltd. | 155 | | | | |
| | group-containing | weight of | Shikoku Chemicals | 2P4MHZ | 0.4 | | | — |
| | polybutadiene- | total resin | Corporation | | | | | |
| | modified aromatic | components) | | | | | | |
| | polyamide resin | | | | | | | |
| | Imidazole-based | | | | | | | |
| | epoxy resin curing agent | | | | | | | |
| | Barium titanate | Dielectric | Nippon Chemical Industrial | | 75 | 75 | 75 | — |
| | | filler content | Co., Ltd. | | | | | |
| | | (parts by weight | | | | | | |
| | | relative to | | | | | | |
| | | 100 parts by | | | | | | |
| | | weight of dielectric | | | | | | |
| | | layer) | | | | | | |
| | Thickness (μm) | | | | 1.2 | 1.0 | 5.0 | — |
| Resin | Polyamide acid | Resin component | Ube Industries, Ltd. | | 100 | | — | 100 |
| layers | varnish | formulation ratio (parts | | | | | | |
| | | by weight relative to | | | | | | |
| | | 100 parts by weight of | | | | | | |
| | | total resin components) | | | | | | |
| | Barium titanate | Dielectric filler content | Nippon Chemical Industrial | | 20 | 40 | — | 40 |
| | | (parts by weight | Co., Ltd. | | | | | |
| | | relative to 100 parts by | | | | | | |
| | | weight of resin layers) | | | | | | |

| | | | | |
|---|---|---|---|---|
| Thickness of each layer (μm) | 2.2 | 2.0 | — | 2.5 |

| | | | | |
|---|---|---|---|---|
| Overall thickness of dielectric and resin layers in double-sided copper clad laminate (μm) | 5.6 | 5.0 | — | — |

*indicates comparative examples.

TABLE 2

| | | | | | Evaluation item | | | | | | | |
|---|---|---|---|---|---|---|---|---|---|---|---|---|
| | | | | | Ex. 1 | Ex. 2 | Ex. 3 | Ex. 4 | Ex. 5 | Ex. 6 | Ex. 7* | Ex. 8* |
| Evaluation | Evaluation | Cp (@1 MHz) | | nF/in² | 3.8 | 5.8 | 7.9 | 4.6 | 6.8 | 10.9 | — | — |
| results | 2 | Df (@1 MHz) | | — | 0.010 | 0.016 | 0.022 | 0.005 | 0.008 | 0.010 | — | — |
| | Evaluation | BDV | | kV | 1.5 | 0.6 | 0.5 | 1.3 | 0.8 | 0.4 | — | — |
| | 3 | | | | | | | | | | | |
| | Evaluation | Peel strength in | | kgf/cm | 1.7 | 1.7 | 2.1 | 0.6 | 0.7 | 0.5 | — | — |
| | 4 | normal state | | Surface | Resin | Resin | Resin | Resin | Resin | Resin | — | — |
| | | (circuit adhesion) | | at break | layer- | layer- | layer- | layer- | layer- | layer- | | |
| | | | | | dielectric | dielectric | dielectric | dielectric | dielectric | dielectric | | |
| | | | | | layer | layer | layer | layer | layer | layer | | |
| | | | | | interface | interface | interface | interface | interface | interface | | |
| | Evaluation | Peel strength after | | kgf/cm | 1.6 | 1.4 | 1.5 | 0.8 | 0.8 | 0.8 | — | — |
| | 5 | heating | | Surface | Resin | Copper | Copper | Resin | Resin | Resin | | |
| | | (circuit adhesion) | | at break | layer- | foil- | foil- | layer- | layer- | layer- | | |
| | | | | | dielectric | resin | resin | dielectric | dielectric | dielectric | | |
| | | | | | layer | layer | layer | layer | layer | layer | | |
| | | | | | interface | interface | interface | interface | interface | interface | | |
| | Evaluation | Tensile | Overall | MPa | 105 | 102 | 95 | 122 | 114 | 100 | — | — |
| | 6 | strength | Dielectric | | 54 | 54 | 54 | 32 | 32 | 32 | — | — |
| | | | layer | | | | | | | | | |
| | | | Resin | | 137 | 127 | 117 | 137 | 127 | 117 | — | — |
| | | | layers | | | | | | | | | |

| | | | | | | | | | | |
|---|---|---|---|---|---|---|---|---|---|---|
| | Elongation | % | 22.7 | 20.6 | 10.1 | 26.8 | 28.5 | 8.8 | — | — |
| Evaluation | Puncture strength | N | 3.8 | 1.8 | 1.1 | 3.5 | 2.0 | 0.8 | — | — |
| 7 | | | | | | | | | | |

*indicates comparative examples. In the tensile strength of Evaluation 6, “Overall” refers to the tensile strength of the resin film (resin layers and dielectric layer).

1. A double-sided copper clad laminate having copper foil adhered onto both surfaces of a dielectric layer,
wherein the dielectric layer has a thickness of 0.1 μm or more and 2.0 μm or less, and
wherein the double-sided copper clad laminate further comprises a pair of resin layers arranged in contact with the copper foil between the dielectric layer and the copper foil.

2. The double-sided copper clad laminate according to claim 1, wherein a tensile strength of the resin layers is larger than a tensile strength of the dielectric layer.

3. The double-sided copper clad laminate according to claim 1, wherein an overall tensile strength of the dielectric layer and the resin layers is 50 MPa or more and 200 MPa or less.

4. The double-sided copper clad laminate according to claim 1, wherein an overall puncture strength of the dielectric layer and the resin layers is 0.6 N or more.

5. The double-sided copper clad laminate according to claim 1, wherein at least one of the resin layers and the dielectric layer comprises a dielectric filler.

6. The double-sided copper clad laminate according to claim 5, wherein when the dielectric layer comprises the dielectric filler, a content of the dielectric filler in the dielectric layer is 10 parts by weight or more and 90 parts by weight or less relative to 100 parts by weight of the dielectric layer.

7. The double-sided copper clad laminate according to claim 5, wherein when the resin layers comprise the dielectric filler, a content of the dielectric filler in the resin layers is 10 parts by weight or more and 80 parts by weight or less relative to 100 parts by weight of the resin layers.

8. The double-sided copper clad laminate according to claim 5, wherein a content of the dielectric filler in the resin layers relative to 100 parts by weight of the resin layers is smaller than a content of the dielectric filler in the dielectric layer relative to 100 parts by weight of the dielectric layer.

9. The double-sided copper clad laminate according to claim 5, wherein the resin layers are free from the dielectric filler and the dielectric layer comprises the dielectric filler.

10. The double-sided copper clad laminate according to claim 9, wherein a content of the dielectric filler in the dielectric layer is 10 parts by weight or more and 90 parts by weight or less relative to 100 parts by weight of the dielectric layer.

11. The double-sided copper clad laminate according to claim 1, wherein a glass transition temperature Tg of resin contained in the resin layers is 180° C. or higher.

12. The double-sided copper clad laminate according to claim 1, wherein a glass transition temperature Tg of resin contained in the resin layers is higher than a glass transition temperature Tg of resin contained in the dielectric layer.

13. A capacitor element comprising the double-sided copper clad laminate according to claim 1.

14. A printed wiring board with built-in capacitor, comprising the double-sided copper clad laminate according to claim 1.

15. A method for manufacturing the double-sided copper clad laminate according to claim 1, comprising:
(i) applying a resin layer precursor to a copper foil;
(ii) curing the precursor to obtain a copper foil with resin layer;
(iii) arranging a dielectric layer on a surface of the resin layer; and
(iv) pressing the copper foil with resin layer on which the dielectric layer has been arranged and another copper foil with resin layer produced through the above (i) and (ii), so that the dielectric layer is sandwiched by the resin layers from both sides.
